(19) United States
(12) Patent Application Publication
(10) Pub. No.: US 2024/0040736 A1
(43) Pub. Date: Feb. 1, 2024

(54) ACOUSTICAL REDUCTION AIRFLOW DUCTS

(71) Applicant: Dell Products L.P., Round Rock, TX (US)

(72) Inventors: Eduardo Escamilla, Round Rock, TX (US); Evangelos Koutsavdis, Leander, TX (US); Richard Mark Eiland, Austin, TX (US); Juan Torres-Gonzalez, Round Rock, TX (US); Chris Everett Peterson, Austin, TX (US)

(21) Appl. No.: 17/816,200

(22) Filed: Jul. 29, 2022

(51) Int. Cl. H05K 7/14; H05K 7/20; G10K 11/16

(52) U.S. Cl. CPC H05K 7/1488; H05K 7/20145; G10K 11/161

(57) ABSTRACT

In one or more embodiments, one or more systems may comprise a system for reducing acoustic energy in a chassis, the system comprising an acoustically absorbent material configured to fill a volume in the chassis between a set of fans and a set of components. A plurality of ducts formed in the acoustically absorbent material prevents turbulent shedding around obstacles and areas of recirculation to streamline the airflows and the acoustically absorbent material absorbs acoustic energy traveling through the ducts.

### BACKGROUND

### Field of the Disclosure

This disclosure relates generally to information handling systems and more particularly to reducing the effects of acoustic energy in a chassis of an information handling system.

### Description of the Related Art

As the value and use of information continues to increase, individuals and businesses seek additional ways to process and store information. One option available to users is information handling systems. An information handling system generally processes, compiles, stores, and/or communicates information or data for business, personal, or other purposes thereby allowing users to take advantage of the value of the information. Because technology and information handling needs and requirements vary between different users or applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, airline reservations, enterprise data storage, or global communications. In addition, information handling systems may include a variety of hardware and software components that may be configured to process, store, and communicate information and may include one or more computer systems, data storage systems, and networking systems.

### SUMMARY

One or more embodiments may be directed to a system for reducing acoustic energy in a chassis containing a set of structures, a plurality of components and a plurality of fans. The system may comprise an acoustically absorbent material configured to fill a volume in the chassis between the plurality of fans and a set of the plurality of components and a plurality of acoustic airflow ducts formed in the acoustically absorbent material, wherein each acoustic airflow duct is configured with an internal surface shaped to guide an airflow to a fan of the plurality of fans.

In some embodiments, the internal structure is shaped based on a set of streamlines associated with the airflow entering the fan. In some embodiments, the acoustically absorbent material is configured to absorb incident sound waves associated with the fan and an airflow generated by the fan.

In some embodiments, a component of the plurality of components is configurable to process information at a processing speed in a range of processing speeds, the fan operating at the fan speed produces the acoustic energy at a frequency of a range of frequencies, the component is subject to a decrease in the processing speed due to the acoustic energy produced at the frequency, and the acoustically absorbent material is configured to absorb at least a portion of the acoustic energy at the frequency.

In some embodiments, the component comprises a hard disk drive (HDD). In some embodiments, the system is positioned between the HDD and the fan, wherein the HDD is upstream of the fan.

In some embodiments, an airflow duct of the plurality of acoustic airflow ducts is configured to guide an airflow around a structure. In some embodiments, the structure comprises a portion of a backplane.

### BRIEF DESCRIPTION OF THE DRAWINGS

For a more complete understanding of the present disclosure and its features/advantages, reference is now made to the following description, taken in conjunction with the accompanying drawings, which are not drawn to scale, and in which:

FIG. 1 depicts an example of an information handling system in a chassis having multiple fans generating multiple airflows;

FIG. 2 depicts a partial perspective view of a portion of a chassis with a plurality of acoustical reduction airflow ducts, in accordance with some embodiments;

FIG. 3 depicts a partial perspective view of a portion of a chassis with a system of acoustical reduction airflow ducts, in accordance with some embodiments;

FIG. 4 depicts a chart illustrating simulated acoustic noise levels for an example of an information handling system in a chassis having multiple fans generating multiple airflows with no acoustical ducts and an information handling system in a chassis having multiple fans generating multiple airflows with a system of acoustical reduction airflow ducts;

FIG. 5 depicts a chart illustrating simulated sound pressure levels experienced by hard disk drives in an example of an information handling system in a chassis having multiple fans generating multiple airflows at 40% PWM duty cycle with no acoustical ducts and an information handling system in a chassis having multiple fans generating multiple airflows with a system of acoustical reduction airflow ducts; and

FIG. 6 depicts a chart illustrating simulated sound pressure levels experienced by hard disk drives in an example of an information handling system in a chassis having multiple fans generating multiple airflows at 100% PWM duty cycle with no acoustical ducts and an information handling system in a chassis having multiple fans generating multiple airflows with a system of acoustical reduction airflow ducts.

### DETAILED DESCRIPTION

In the following description, details are set forth by way of example to facilitate discussion of the disclosed subject matter. It should be apparent to a person of ordinary skill in the field, however, that the disclosed embodiments are examples and not exhaustive of all possible embodiments.

As used herein, a reference numeral refers to a class or type of entity, and any letter following such reference numeral refers to a specific instance of a particular entity of that class or type. Thus, for example, a hypothetical entity referenced by ‘12A’ may refer to a particular instance of a particular class/type, and the reference ‘12’ may refer to a collection of instances belonging to that particular class/type or any one instance of that class/type in general.

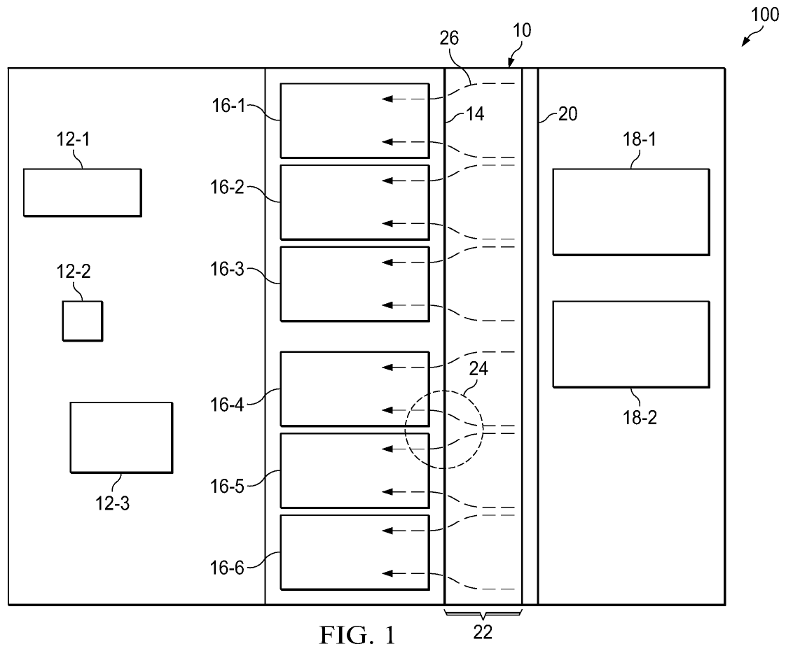

Turning now to FIG. 1, an example of an information handling system is illustrated, according to one or more embodiments. An information handling system (IHS) may include a hardware resource or an aggregate of hardware resources operable to compute, classify, process, transmit, receive, retrieve, originate, switch, store, display, manifest, detect, record, reproduce, handle, and/or utilize various forms of information, intelligence, or data for business, scientific, control, entertainment, or other purposes, according to one or more embodiments. For example, an IHS may be a personal computer, a desktop computer system, a laptop computer system, a server computer system, a mobile device, a tablet computing device, a personal digital assistant (PDA), a consumer electronic device, an electronic music player, an electronic camera, an electronic video player, a wireless access point, a network storage device, or another suitable device and may vary in size, shape, performance, functionality, and price. In one or more embodiments, a portable IHS may include or have a form factor of that of or similar to one or more of a laptop, a notebook, a telephone, a tablet, and a PDA, among others. For example, a portable IHS may be readily carried and/or transported by a user (e.g., a person). In one or more embodiments, components of an IHS may include one or more storage devices, one or more communications ports for communicating with external devices as well as various input and output (I/O) devices, such as a keyboard, a mouse, and a video display, among others. In one or more embodiments, IHS may include one or more buses operable to transmit communication between or among two or more hardware components. In one example, a bus of an IHS may include one or more of a memory bus, a peripheral bus, and a local bus, among others. In another example, a bus of an IHS may include one or more of a Micro Channel Architecture (MCA) bus, an Industry Standard Architecture (ISA) bus, an Enhanced ISA (EISA) bus, a Peripheral Component Interconnect (PCI) bus, HyperTransport (HT) bus, an inter-integrated circuit (I²C) bus, a serial peripheral interface (SPI) bus, a low pin count (LPC) bus, an enhanced serial peripheral interface (eSPI) bus, a universal serial bus (USB), a system management bus (SMBus), and a Video Electronics Standards Association (VESA) local bus, among others.

In one or more embodiments, an IHS may include firmware that controls and/or communicates with one or more hard drives, network circuitry, one or more memory devices, one or more I/O devices, and/or one or more other peripheral devices. For example, firmware may include software embedded in an IHS component utilized to perform tasks. In one or more embodiments, firmware may be stored in non-volatile memory, such as storage that does not lose stored data upon loss of power. In one example, firmware associated with an IHS component may be stored in non-volatile memory that is accessible to one or more IHS components. In another example, firmware associated with an IHS component may be stored in non-volatile memory that may be dedicated to and includes part of that component. For instance, an embedded controller may include firmware that may be stored via non-volatile memory that may be dedicated to and includes part of the embedded controller.

An IHS may include a processor, a volatile memory medium, non-volatile memory media, an I/O subsystem, and a network interface. Volatile memory medium, non-volatile memory media, I/O subsystem, and network interface may be communicatively coupled to processor. In one or more embodiments, one or more of volatile memory medium, non-volatile memory media, I/O subsystem, and network interface may be communicatively coupled to processor via one or more buses, one or more switches, and/or one or more root complexes, among others. In one example, one or more of a volatile memory medium, non-volatile memory media, an I/O subsystem, a and network interface may be communicatively coupled to the processor via one or more PCI-Express (PCIe) root complexes. In another example, one or more of an I/O subsystem and a network interface may be communicatively coupled to processor via one or more PCIe switches.

In one or more embodiments, the term “memory medium” may mean a “storage device”, a “memory”, a “memory device”, a “tangible computer readable storage medium”, and/or a “computer-readable medium”. For example, computer-readable media may include, without limitation, storage media such as a direct access storage device (e.g., a hard disk drive, a floppy disk, etc.), a sequential access storage device (e.g., a tape disk drive), a compact disk (CD), a CD-ROM, a digital versatile disc (DVD), a random access memory (RAM), a read-only memory (ROM), a one-time programmable (OTP) memory, an electrically erasable programmable read-only memory (EEPROM), and/or a flash memory, a solid state drive (SSD), or any combination of the foregoing, among others.

In one or more embodiments, one or more protocols may be utilized in transferring data to and/or from a memory medium. For example, the one or more protocols may include one or more of small computer system interface (SCSI), Serial Attached SCSI (SAS) or another transport that operates with the SCSI protocol, advanced technology attachment (ATA), serial ATA (SATA), a USB interface, an Institute of Electrical and Electronics Engineers (IEEE) 1394 interface, a Thunderbolt interface, an advanced technology attachment packet interface (ATAPI), serial storage architecture (SSA), integrated drive electronics (IDE), or any combination thereof, among others.

A volatile memory medium may include volatile storage such as, for example, RAM, DRAM (dynamic RAM), EDO RAM (extended data out RAM), SRAM (static RAM), etc. One or more of non-volatile memory media may include nonvolatile storage such as, for example, a read only memory (ROM), a programmable ROM (PROM), an erasable PROM (EPROM), an electrically erasable PROM, NVRAM (non-volatile RAM), ferroelectric RAM (FRAM), a magnetic medium (e.g., a hard drive, a floppy disk, a magnetic tape, etc.), optical storage (e.g., a CD, a DVD, a BLU-RAY disc, etc.), flash memory, a SSD, etc. In one or more embodiments, a memory medium can include one or more volatile storages and/or one or more nonvolatile storages.

In one or more embodiments, a network interface may be utilized in communicating with one or more networks and/or one or more other information handling systems. In one example, network interface may enable an IHS to communicate via a network utilizing a suitable transmission protocol and/or standard. In a second example, a network interface may be coupled to a wired network. In a third example, a network interface may be coupled to an optical network. In another example, a network interface may be coupled to a wireless network. In one instance, the wireless network may include a cellular telephone network. In a second instance, the wireless network may include a satellite telephone network. In another instance, the wireless network may include a wireless Ethernet network (e.g., a Wi-Fi network, an IEEE 802.11 network, etc.).

In one or more embodiments, a network interface may be communicatively coupled via a network to a network storage resource. For example, the network may be implemented as, or may be a part of, a storage area network (SAN), personal area network (PAN), local area network (LAN), a metropolitan area network (MAN), a wide area network (WAN), a wireless local area network (WLAN), a virtual private network (VPN), an intranet, an Internet or another appropriate architecture or system that facilitates the communication of signals, data and/or messages (generally referred to as data). For instance, the network may transmit data utilizing a desired storage and/or communication protocol, including one or more of Fibre Channel, Frame Relay, Asynchronous Transfer Mode (ATM), Internet protocol (IP), other packet-based protocol, Internet SCSI (iSCSI), or any combination thereof, among others.

In one or more embodiments, a processor may execute processor instructions in implementing at least a portion of one or more systems, at least a portion of one or more flowcharts, at least a portion of one or more methods, and/or at least a portion of one or more processes. In one example, a processor may execute processor instructions from one or more memory media in implementing at least a portion of one or more systems, at least a portion of one or more flowcharts, at least a portion of one or more methods, and/or at least a portion of one or more processes. In another example, a processor may execute processor instructions via a network interface in implementing at least a portion of one or more systems, at least a portion of one or more flowcharts, at least a portion of one or more methods, and/or at least a portion of one or more processes.

In one or more embodiments, a processor may include one or more of a system, a device, and an apparatus operable to interpret and/or execute program instructions and/or process data, among others, and may include one or more of a microprocessor, a microcontroller, a digital signal processor (DSP), an application specific integrated circuit (ASIC), and another digital or analog circuitry configured to interpret and/or execute program instructions and/or process data, among others. In one example, a processor may interpret and/or execute program instructions and/or process data stored locally (e.g., via memory media and/or another component of an IHS). In another example, a processor may interpret and/or execute program instructions and/or process data stored remotely (e.g., via a network storage resource).

In one or more embodiments, an I/O subsystem may represent a variety of communication interfaces, graphics interfaces, video interfaces, user input interfaces, and/or peripheral interfaces, among others. For example, an I/O subsystem may include one or more of a touch panel and a display adapter, among others. For instance, a touch panel may include circuitry that enables touch functionality in conjunction with a display that is driven by a display adapter.

A non-volatile memory medium may include an operating system (OS) and applications (APPs). In one or more embodiments, one or more of an OS and APPs may include processor instructions executable by a processor. In one example, a processor may execute processor instructions of one or more of OS and APPs via a non-volatile memory medium. In another example, one or more portions of the processor instructions of one or more of an OS and APPs may be transferred to a volatile memory medium and a processor may execute the one or more portions of the processor instructions.

Non-volatile memory medium may include information handling system firmware (IHSFW). In one or more embodiments, IHSFW may include processor instructions executable by a processor. For example, IHSFW may include one or more structures and/or one or more functionalities of and/or compliant with one or more of a basic input/output system (BIOS), an Extensible Firmware Interface (EFI), a Unified Extensible Firmware Interface (UEFI), and an Advanced Configuration and Power Interface (ACPI), among others. In one instance, a processor may execute processor instructions of IHSFW via non-volatile memory medium. In another instance, one or more portions of the processor instructions of IHSFW may be transferred to volatile memory medium, and processor may execute the one or more portions of the processor instructions of IHSFW via volatile memory medium.

A chassis 10 may include a plurality of fans 14 for generating airflows to cool components 12 and 18. Each fan 16 generates an airflow, wherein components 12 may be located downstream of fans 16 and components 18 may be located upstream of fans 16. The operation of fans 16 may be necessary to cool components 12 and 18, but their operation may negatively affect the performance of components 18. For example, fans 16 produce acoustic energy (e.g., noise) when generating airflows 26 due to the fan blades slicing through air. Also, fans 16 may produce noise because sound pressure scales with the 5^{th} power of fan speed (measured in revolutions per minute or RPM). Furthermore, referring to area 24, airflows 26 may contact fan structures 14 or chassis structures 20, causing turbulent shedding. Thus, a structure such as backplane 20 or the fan housings 14 may also be a source of noise that could negatively affect the performance of HDDs 18.

One approach to reducing noise in chassis 10 may be to operate fans 16 at reduced fan speeds. The tradeoff may be that fans 16 also generate less airflow so the ability to cool components 12 is reduced. As a result, an information handling system in chassis 10 may be forced to operate at lower power settings and therefore a reduced performance overall.

Another approach is to add foam to a cover in chassis 10. The foam may absorb some noise, but typically occupies a small footprint and noise may still affect the HDDs 18.

Another approach is to add interior mufflers. These occupy space and may increase impedance to reduce airflow speed through chassis 10.

Embodiments disclosed herein include a system for reducing acoustic energy produced by fans 16 to reduce the possibility of damage or negative performance of components such as HDDs.

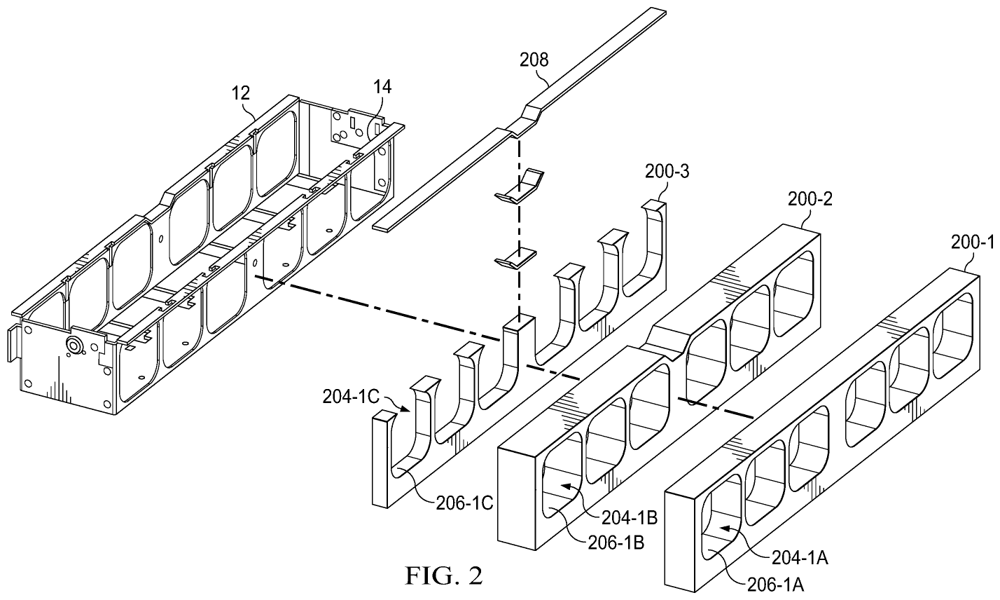

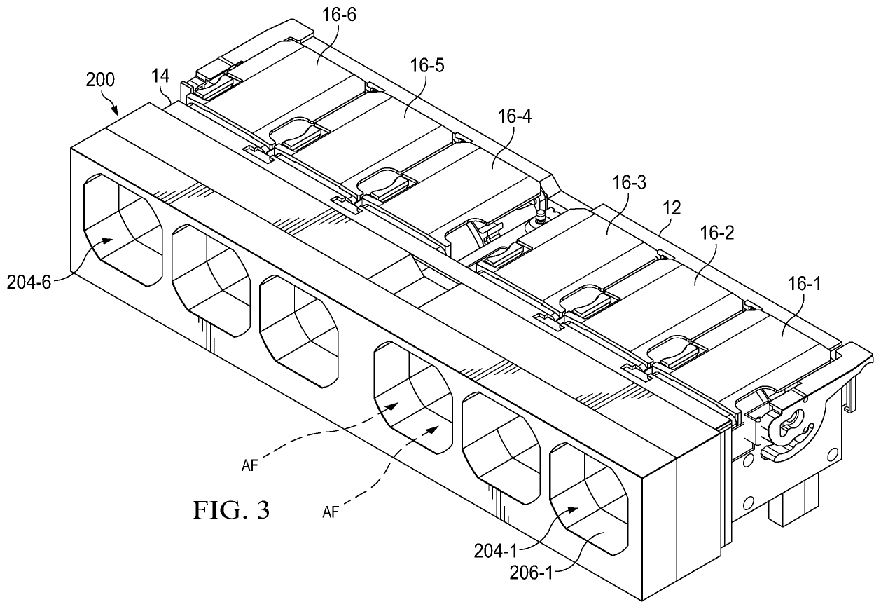

Referring to FIG. 2 and FIG. 3, embodiments of a system for reducing noise produced by fans 16 comprises an acoustically absorbent material 200 configured with a height, length and width to fill a volume in chassis 10 between the plurality of fans 16 and a set of the plurality of components 12 and 18, wherein the acoustically absorbent material 200 comprises a plurality of acoustic airflow ducts 204. Furthermore, each acoustic airflow duct 204 is configured with an internal surface 206 based on a streamline of an airflow 26 to guide an airflow 26 to a fan 16 of the plurality of fans 16, discussed in greater detail below.

As depicted in FIG. 2, in some embodiments, acoustically absorbent material 200 may comprise a plurality of sections (e.g., sections 200-1, 200-2, 200-3), which may allow a user to select a combination of sections of different dimensions to fill a volume and accommodate structures 14 in chassis 10. Sections 200-1, 200-2 and 200-3 may be positioned in chassis 10 such that portions (e.g., 204-1A, 204-1B and 204-1C of acoustic airflow ducts 204 are aligned. In some embodiments, one or more sections (e.g., section 200-3) may form part of acoustic airflow ducts (e.g., part of portion 204-1C) and cross-member 208 may be positioned to substantially close the portion (e.g., 204-1C) into an acoustic airflow duct 204 with a continuous internal surface 206.

As depicted in FIG. 3, in some embodiments, acoustically absorbent material 200 may be formed as a single unit, which may an internal surface 206 of each acoustic airflow duct 204 is a continuous surface.

Acoustically absorbent material 200 may be formed with a length, width and height to fill volume 22 in chassis 10 between fans 16 and HDD 18 such that substantially all acoustic energy produced by fans 16 must propagate through acoustic airflow ducts 204 to reach HDDs 18.

As used herein, the term “acoustically absorbent” may refer to a material that absorbs incident sound waves, regardless of the source. Thus, acoustically absorbent material 200 may absorb incident sound waves produced by fan blades slicing through air, sound pressure associated with the 5^{th} power of the RPM of fan 16, or turbulent shedding of airflows 26 around structures such as backplane 20 or the fan housings 14.

In some embodiments, the shape of internal surface 26 may be based on computational fluid dynamics (CFD) to ensure fans 16 may operate at lower fan speeds (and produce less acoustic noise) and also reduce losses associated with turbulence to maintain (or increase) the volumetric flow rate.

In some embodiments, a solution to the Navier-Stokes equations may provide a flow path of an airflow 26 without turbulent shedding or areas of recirculation, including streamlines as lines with a tangent velocity vector. In some embodiments, one or more acoustic airflow ducts 204 may be formed based on a set of streamlines associated with a fan 16, wherein the acoustic airflow duct 204 may be formed with an internal surface 26 shaped based on the streamlines for airflow 26 entering that fan 16.

In some embodiments, a flow path of an airflow 26 may be based on a solution to the Navier-Stokes equations. In some embodiments, acoustically absorbent material 200 may be configured into a plurality of airflow ducts 204 with internal surfaces 26 for reducing or eliminating areas of recirculation that may result in lower airflow speed. In some embodiments, one or more acoustic airflow ducts 204 may be formed based on a solution to the Navier-Stokes equations to avoid a set of areas of recirculation associated with an airflow 26, wherein the acoustic airflow duct 204 may be formed in acoustically absorbent material 200 based on preventing areas of recirculation from forming. Reducing or preventing areas of recirculation reduces the propensity for turbulence in airflows 26, which may allow fans 16 to operate at lower fan speeds (reducing the sound waves produced by fan blades slicing through air and the sound pressure associated with the 5^{th} power of the RPM of fans 16) but generate the same airflow 26. Reducing or preventing areas of recirculation may also reduce turbulent shedding of airflows 26.

Thus, embodiments disclosed herein may comprise acoustically absorbent material 200 configured to fill a portion of a volume in chassis 10 to prevent areas of recirculation and turbulent shedding and may further include acoustic airflow ducts 204 formed based on a solution to the Navier-Stokes equations to avoid areas of recirculation and turbulent shedding. The acoustically absorbent material 200 further absorbs acoustic energy to reduce the amount of acoustic energy that reaches HDDs 18.

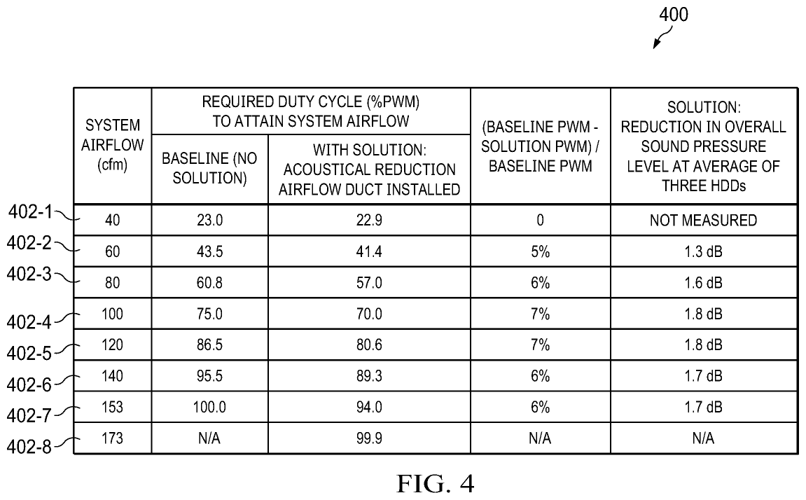

FIG. 4 depicts a chart illustrating improvement in system airflow with reduced fan speed and sound pressure. For example, referring to row 402-1 as a baseline, for an airflow of 40 CFM (cubic feet per minute), fans 16 may typically operate at approximately 23% PWM. In this configuration, any acoustic energy may affect HDDs 18.

As illustrated in row 402-2, for a system airflow of 60 CFM, fans 16 in chassis 10 without embodiments described herein may operate at approximately 43.5% PWM. However, for chassis having embodiments described herein, fans 16 may operate at approximately 41.4% PWM (approximately 5% reduction in fan speed) and generate the same airflow but produce approximately 1.3 dB less sound pressure. In this and the following configurations, the amount of acoustic energy that can affect HDDs 18 is reduced by acoustically absorbent material 200 configured to fill a portion of a volume in chassis 10 to prevent areas of recirculation and turbulent shedding and acoustic airflow ducts 204 formed based on a solution to the Navier-Stokes equations to avoid areas of recirculation and turbulent shedding. Furthermore, a portion of the sound pressure may be absorbed by acoustically absorbent material 200, further reducing the amount of acoustic energy that could otherwise negatively affect the performance of HDDs 18.

Referring to row 402-7, fans 16 operating in chassis 10 without embodiments described herein may generate 153 CFM of airflow when operating at 100% PWM, while fans 16 operating in chassis 10 with embodiments described herein may generate the same airflow (153 CFM) when operating at approximately 94.9% PWM but produce approximately 1.7 dB less sound pressure).

Furthermore, referring to row 402-8, fans 16 operating in chassis 10 with embodiments described herein may generate a higher airflow (approximately 173 CFM) when operating at approximately 99.9% PWM.

In addition to enabling fans 16 to generate the same airflow 26 at lower fan speeds and/or operate at higher fan speeds but produce the same or less noise level, embodiments may effectively reduce noise at frequencies more harmful to components such as HDDs 18.

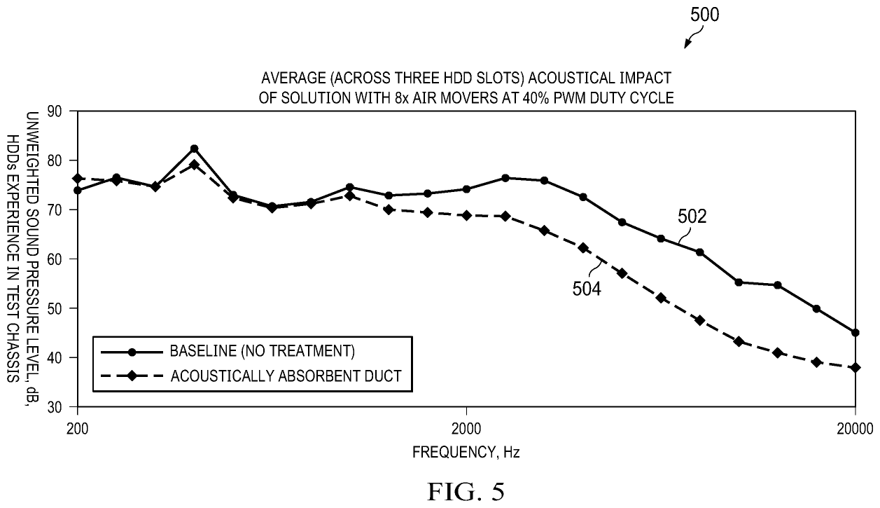

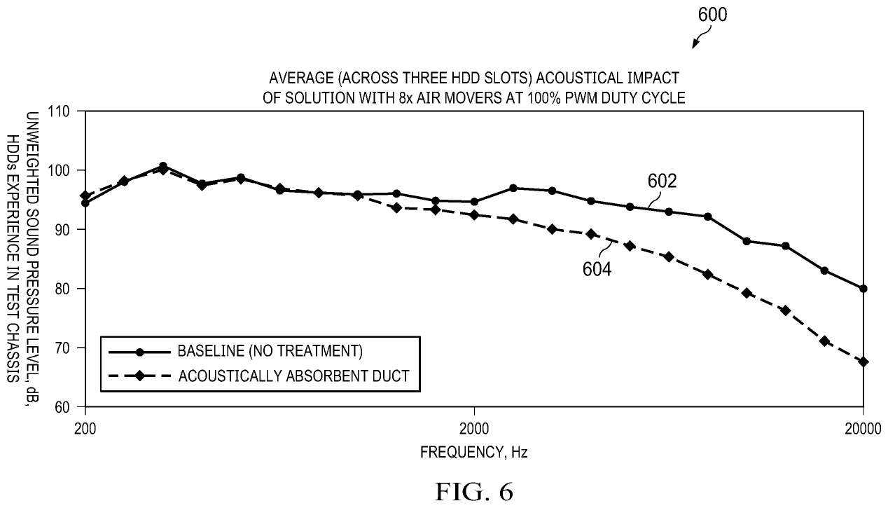

FIG. 5 and FIG. 6 depict graphs 500, 600 of unweighted sound pressure levels (in dB) in relative to average acoustical impact of fans operating at 40% PWM and 100%, respectively. As illustrated in graph 500, baseline 502 corresponds to a test chassis 10 having no acoustical reduction system and line 504 corresponds to test chassis 10 with acoustically absorbent material 200 configured with a plurality of airflow ducts 204.

As illustrated in both graphs, HDDs 18 in a test chassis 10 may experience similar levels of acoustic energy at frequencies between 200 Hz to approximately 1500 Hz regardless of the presence of acoustically absorbent material 200, but HDDs 18 in a test chassis 10 with acoustically absorbent material 200 formed with a plurality of acoustical reduction airducts 204 may experience lower levels of acoustic energy at frequencies greater than approximately 1500 Hz. Notably, graphs 500 and 600 generally illustrate acoustic energy over a range of frequencies. For example, as mentioned above, embodiments may allow fans 16 to operate at lower fan speeds (and produce less acoustic noise). However, embodiments disclosed herein may operate fans 16 at lower fan speeds with a corresponding decrease in acoustic noise and possibly at a lower frequency.

For HDDs 18, acoustical attenuation is most critical in the frequency range of 1000-20000 Hz. In this range, an embodiment of a system comprising acoustically absorbent material 200 formed with a plurality of airflow ducts 204 reduced the acoustic energy an average of approximately 3.5 dB.

Thus, embodiments may provide a system that reduces areas of recirculation and/or turbulent shedding such that fans 16 may operate at lower fan speeds to produce less acoustic energy (noise) but generate the same (or higher) airflow. Furthermore, acoustically absorbent material 200 may be formed into airflow ducts 204 to ensure airflows follow streamlines and may absorb at least some of the acoustic energy produced by fans 16 at a frequency or range of frequencies that could affect the performance of components in chassis 10.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A system for reducing acoustic energy in a chassis containing a set of structures, a plurality of components and a plurality of fans, the system comprising:
an acoustically absorbent material configured to fill a volume in the chassis between the plurality of fans and a set of the plurality of components; and
a plurality of acoustic airflow ducts formed in the acoustically absorbent material, wherein each acoustic airflow duct is configured with an internal surface shaped to guide an airflow to a fan of the plurality of fans.

2. The system of claim 1, wherein the internal structure is shaped based on a set of streamlines associated with the airflow entering the fan.

3. The system of claim 1, wherein
a component of the plurality of components is configurable to process information at a processing speed in a range of processing speeds;
the fan operating at the fan speed produces the acoustic energy at a frequency of a range of frequencies,
the component is subject to a decrease in the processing speed due to the acoustic energy produced at the frequency; and
the acoustically absorbent material is configured to absorb at least a portion of the acoustic energy at the frequency.

4. The system of claim 3, wherein the acoustically absorbent material is configured to absorb incident sound waves associated with the fan and an airflow generated by the fan.

5. The system of claim 4, wherein the component comprises a hard disk drive (HDD).

6. The system of claim 5, wherein the system is positioned between the HDD and the fan, wherein the HDD is upstream of the fan.

7. The system of claim 1, wherein an airflow duct of the plurality of acoustic airflow ducts is configured to guide an airflow around a structure.

8. The system of claim 7, wherein the internal surface of the airflow duct of the plurality of acoustic airflow ducts is shaped based on a set of streamlines associated with the airflow entering the fan.

9. The system of claim 7, wherein the structure comprises a portion of a backplane.

10. A chassis for an information handling system comprising a plurality of components and a plurality of fans, the chassis comprising:
a set of structures, wherein at least one structure is positioned between the plurality of components and the plurality of fans; and
a system for reducing acoustic energy in the chassis, comprising:
an acoustically absorbent material configured with a height, length and width to fill a portion of the chassis between the plurality of fans and a set of the plurality of components; and
a plurality of acoustic airflow ducts formed in the acoustically absorbent material, wherein each acoustic airflow duct is configured with an internal surface shaped to guide an airflow to a fan of the plurality of fans.

11. The chassis of claim 10, wherein the internal structure is shaped based on a set of streamlines associated with the airflow entering the fan.

12. The chassis of claim 10, wherein
a component of the plurality of components is configurable to process information at a processing speed in a range of processing speeds;
the fan operating at the fan speed produces the acoustic energy at a frequency of a range of frequencies,
the component is subject to a decrease in the processing speed due to the acoustic energy produced at the frequency; and
the acoustically absorbent material is configured to absorb at least a portion of the acoustic energy at the frequency.

13. The chassis of claim 12, wherein the acoustically absorbent material is configured to absorb incident sound waves associated with the fan and an airflow generated by the fan.

14. The chassis of claim 13, wherein the component comprises a hard disk drive (HDD).

15. The chassis of claim 14, wherein the system is positioned between the HDD and the fan, wherein the HDD is upstream of the fan.

16. The chassis of claim 11, wherein an airflow duct of the plurality of acoustic airflow ducts is configured to guide an airflow around a structure of the set of structures.

17. The chassis of claim 16, wherein the internal surface of the airflow duct of the plurality of acoustic airflow ducts is shaped based on a set of streamlines associated with the airflow entering the fan.

18. The chassis of claim 16, wherein the structure comprises a portion of a backplane.
